(19) United States
(12) Patent Application Publication
(10) Pub. No.: US 2007/0063223 A1
(43) Pub. Date: Mar. 22, 2007

(54) Semiconductor device having pattern-dummy and method for manufacturing the same using pattern-dummy

(75) Inventor: Jae Seung Choi, Gyunggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Gyunggi-do (KR)

(21) Appl. No.: 11/321,764

(22) Filed: Dec. 28, 2005

(30) Foreign Application Priority Data
Sep. 20, 2005 (KR) 2005-87205

(51) Int. Cl. H01L 27/10; H01L 21/3205

(52) U.S. Cl. 257/202; 438/587; 257/211; 257/E23.07

(57) ABSTRACT

A semiconductor device includes a main pattern disposed to overlap with an active region that is surrounded by a device isolating region, and the dummy pattern disposed on the device isolating region to be spaced apart from the active region by a predetermined distance. A distance between the dummy pattern and the active region is determined in accordance with a predetermined design rule. In particular, the semiconductor device includes a plurality of connector dummy patterns or auxiliary dummy patterns to achieve a stabilized firm dummy pattern.

### CROSS REFERENCE TO RELATED APPLICATIONS

The present application claims priority to Korean Patent Application No. 10-2005-0087205, filed Sep. 20, 2005 and is incorporated by reference.

### BACKGROUND OF THE INVENTION

The present invention relates to a semiconductor device and a method for manufacturing the same, and more particularly to a semiconductor device having a dummy pattern and a semiconductor device manufacturing method using the dummy pattern.

Generally, a semiconductor device includes many patterns. The patterns included in the semiconductor device may have the same shape as each other or have different shapes. Even when the patterns have the same shape, the patterns may be spaced apart from one another by a narrow, moderate, or wide distance.

FIG. 1 is a layout view illustrating various patterns of a conventional semiconductor device.

Referring to FIG. 1, the semiconductor device may include a dense pattern structure, designated as reference letter A, in which a distance between neighboring main patterns 1 is relatively narrow. Alternatively, the semiconductor device may include a semi-dense pattern structure, designated as reference letter B, in which a distance between the neighboring main patterns 1 is wider than that of the dense pattern structure, or that of an isolated pattern structure designated as reference letter C, in which a single main pattern 1 is isolated from other neighboring patterns by a sufficient distance. In all cases described above, the main patterns 1 are disposed to overlap with an active region 2. The active region 2 contains one or more conductive contacts, for example bit line contacts 3, disposed thereon. Also, each main pattern 1 is connected at an end thereof to a pad, which is disposed on a device isolating region surrounding the active region 2.

To pattern the various structures above, a photolithography process is generally used. However, recent increases in the degree of integration of devices reveal the limitations of the photolithography process. To overcome the limitations of the photolithography process, manufacturers have conventionally attempted to use an illuminating system having a high numeral aperture (NA) and a short wavelength light source, or various processes associated with resolution enhancement technology (RET). Using the illuminating system having a high NA or RET achieves an increase in the margin of the photolithography process, particularly in the case of the dense pattern or semi-dense pattern. However, when the conventional solution is applied to the isolated pattern, it may cause the unfavorable side effect of reducing the margin of depth of focus (DOF).

Moreover, in the case of the isolated pattern it is necessary to apply a higher bias than the dense pattern when an etching process is performed after completing the photolithography process. Therefore, the critical dimension (CD) should be reduced during the photolithography process, which is very difficult. Another problem of the conventional solution as stated above is that the uniformity of the CD may be greatly deteriorated due to degradation in the profile of the photoresist after completion of the photolithography process. For this reason, auxiliary patterns have been conventionally used to eliminate the above problems.

FIG. 2 is a layout view illustrating a conventional photomask having an auxiliary pattern for use in the patterning of a semiconductor device pattern. In FIG. 2, the same reference numerals as those of FIG. 1 denote the same elements, and thus, a detailed description of the same elements will be omitted.

Referring to FIG. 2, the conventional photomask is configured in such a way that a pair of auxiliary patterns 4 are arranged at opposite sides of a main pattern 1 having an isolated pattern structure. The auxiliary patterns 4 have a stripe shape parallel to the main pattern 1, and are spaced apart from the main pattern 1 by a predetermined distance. Instead of the two auxiliary patterns 4 spaced apart from each other, a single auxiliary pattern or three or more auxiliary patterns may be arranged if necessary.

The auxiliary patterns 4 the effect of increasing the margin of DOF in the case of an isolated pattern. In connection with the auxiliary patterns 4, it is important that the auxiliary patterns are not transferred to the wafer although they are disposed on the photomask to overlap with the active region 2. Transfer of the auxiliary patterns to the wafer causes an unexpected pattern to be disposed on the active region 2, thereby having an unfavorable effect on the operation of the device. Accordingly, the auxiliary patterns should exist only on the photomask, and should not be transferred to the wafer. However, it is difficult to completely prevent the transfer of auxiliary patterns.

### BRIEF SUMMARY OF THE INVENTION

The present invention relates to a semiconductor device having a dummy pattern which can achieve an increase in the margin of depth of focus (DOF) even when an isolated pattern is formed by the use of a photolithography process, and can prevent the dummy pattern from having an unfavorable effect on the operation of the semiconductor device.

The present invention also relates to a method for manufacturing a semiconductor device using a dummy pattern.

In accordance with a first aspect of the present invention, a semiconductor devicecomprises a main pattern disposed to overlap with an active region that is surrounded by a device isolating region, and a dummy pattern disposed on the device isolating region to be spaced apart from the active region by a predetermined distance.

Preferably, the distance between the dummy pattern and the active region may be determined within a range which prevents the dummy pattern from having an unfavorable effect on the operation of the device.

It is also preferable that the distance between the dummy pattern and the active region may be determined according to parasitic capacitance, implant shadow effect, and bonding region formation procedure.

It is also preferable that the dummy pattern have a stripe shape arranged parallel to the main pattern.

It is also preferable that the width of the stripe shaped dummy pattern be determined within a range to restrict parasitic capacitance, to increase the margin of the photolithography process, and to obtain a minimized etching bias.

It is also preferable that the dummy pattern include a plurality of stripe dummy patterns spaced apart from each other.

It is also preferable that the semiconductor device further comprise a plurality of connector dummy patterns for interconnecting ends of the neighboring stripe dummy patterns.

It is also preferable that the semiconductor device further comprise a pair of auxiliary dummy patterns arranged at both ends of the stripe shaped dummy pattern, the auxiliary dummy patterns having a width larger than that of the dummy pattern.

In accordance with a second aspect of the present invention, a semiconductor device comprises first and second main patterns disposed to overlap with the first and second active regions, which are separated from each other by interposing a device isolating region; and a dummy pattern disposed on the device isolating region to be spaced apart from the first and second active regions by predetermined first and second distances, which are determined to prevent the dummy pattern from having an unfavorable effect on the operation of the device, the dummy pattern having the maximum width determined within a range which keeps the predetermined first and second distances within the first and second active regions.

Preferably, the first and second distances between the first and second active regions and the dummy pattern may be determined according to parasitic capacitance, implant shadow effect, and bonding region formation procedure.

In accordance with a third aspect of the present invention, a method for manufacturing a semiconductor device comprises depositing a material layer to be patterned on a semiconductor substrate, in which an active region is surrounded by a device isolating region; depositing a photoresist layer on the material layer; forming a photoresist layer pattern by carrying out photo exposure and development processes by use of a photo mask, the photomask having a first light shielding pattern that corresponds to a material layer pattern to be formed to overlap with the active region, and a second light shielding pattern that corresponds to a dummy pattern to be disposed on the device isolating region while being spaced apart from the active region by a predetermined distance; forming the material layer pattern and the dummy pattern via an etching process that uses the photoresist layer pattern as an etching mask; and removing the photoresist layer pattern.

Preferably, the distance between the dummy pattern and the active region may be determined within a range which prevents the dummy pattern from exerting an unfavorable effect on the operation of the device.

It is also preferable that the distance between the dummy pattern and the active region be determined according to parasitic capacitance, implant shadow effect, and bonding region formation procedure.

It is also preferable that the dummy pattern have a stripe shape arranged parallel to the material layer pattern.

It is also preferable that the width of the stripe shaped dummy pattern be determined within a range which restricts parasitic capacitance in order to increase the margin of the photolithography process and to obtain a minimized etching bias.

It is also preferable that the dummy pattern include a plurality of stripe dummy patterns spaced apart from each other.

In accordance with a fourth aspect of the present invention, a method for manufacturing a semiconductor device comprises depositing a material layer to be patterned on a semiconductor substrate in which an active region is surrounded by a device isolating region; depositing a photoresist layer on the material layer; forming a photoresist layer pattern by carrying out photo exposure and development processes by use of a photomask, the photomask having a first light shielding pattern that corresponds to a material layer pattern to be formed to overlap with the active region, a plurality of second light shielding patterns that correspond to a plurality of stripe dummy patterns to be disposed on the device isolating region while being spaced apart from the active region by a predetermined distance, and a plurality of third light shielding patterns that correspond to a plurality of connector dummy patterns used to interconnect ends of the neighboring stripe dummy patterns; forming the material layer pattern and the dummy patterns via an etching process that uses the photoresist layer pattern as an etching mask; and removing the photoresist layer pattern.

In accordance with a fifth aspect of the present invention, a method for manufacturing a semiconductor device comprises depositing a material layer to be patterned on a semiconductor substrate in which an active region is surrounded by a device isolating region; depositing a photoresist layer on the material layer; forming a photoresist layer pattern by carrying out photo exposure and development processes by use of a photomask, the photomask having a first light shielding pattern that corresponds to a material layer pattern to be formed to overlap with the active region, a second light shielding pattern that corresponds to a dummy pattern to be formed on the device isolating region while being spaced apart from the active region by a predetermined distance, and a pair of third light shielding patterns that correspond to a pair of auxiliary dummy patterns provided at both ends of the dummy pattern, the auxiliary dummy patterns having a width larger than that of the main dummy pattern; forming the material layer pattern and the main and auxiliary dummy patterns via an etching process that uses the photoresist layer pattern as an etching mask; and removing the photoresist layer pattern.

In accordance with a sixth aspect of the present invention, a method for manufacturing a semiconductor device comprises depositing a material layer to be patterned on a semiconductor substrate in which first and second active regions are separated from each other by interposing a device isolating region; depositing a photoresist layer on the material layer; forming a photoresist layer pattern by carrying out photo exposure and development processes by use of a photomask, the photomask having a plurality of first light shielding patterns that correspond to first and second material layer patterns to be formed to overlap with the first and second active regions, and a second light shielding pattern that corresponds to a dummy pattern to be formed on the device isolating region while being spaced apart from the first and second active regions by first and second distances, which are determined to prevent the dummy pattern from having an unfavorable effect on the operation of the device, the dummy pattern having the maximum width within a range that keeps the first and second distances within the first and second active regions; forming the material layer pattern and the dummy pattern via an etching process that uses the photoresist layer pattern as an etching mask; and removing the photoresist layer pattern.

### BRIEF DESCRIPTION OF THE DRAWINGS

FIG. 1 is a layout view illustrating various patterns of a conventional semiconductor device;

FIG. 2 is a layout view illustrating a conventional photo mask having an auxiliary pattern for use in the patterning of a semiconductor device;

FIG. 3 is a layout view illustrating a semiconductor device having a dummy pattern according to the present invention;

FIG. 4 is a layout view illustrating several different examples of dummy patterns for use in the semiconductor device having a dummy pattern according to the present invention;

FIG. 5 is a layout view illustrating a preferred embodiment associated with a semiconductor device having a dummy pattern according to the present invention;

FIG. 6 is a layout view illustrating an undesirable design example associated with a semiconductor device having a dummy pattern according to the present invention;

FIG. 7 is a view illustrating the result of patterning the semiconductor device having a dummy pattern according to the present invention using appropriate energy and optimal focus;

FIG. 8 is a view illustrating the result of patterning the semiconductor device having a dummy pattern according to the present invention using over-energy and defocus; and

FIG. 9 is a sectional view illustrating a method for manufacturing the semiconductor device using a dummy pattern according to the present invention.

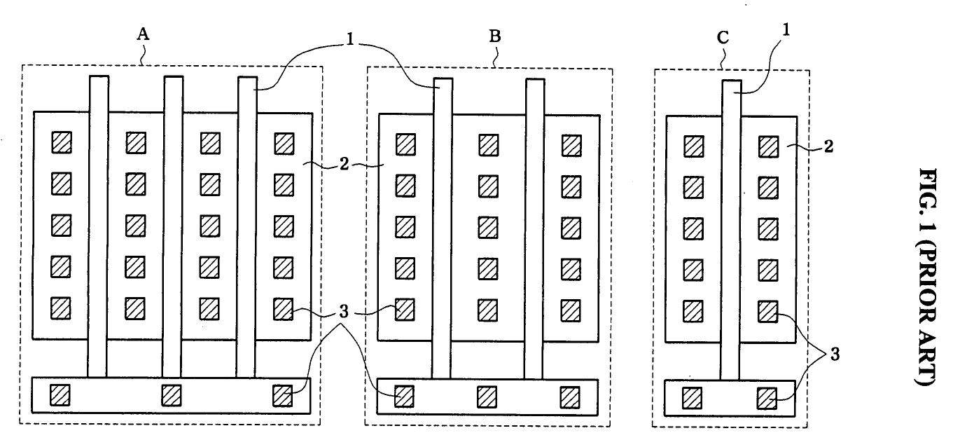

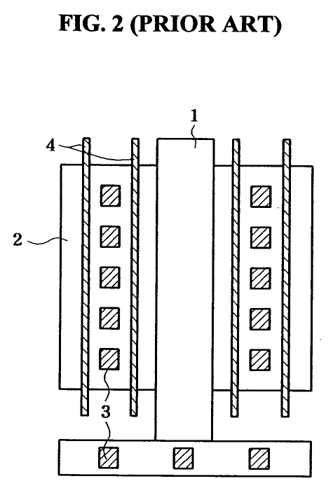

### DETAILED DESCRIPTION OF THE INVENTION

Specific embodiments of the present invention will now be explained with reference to the accompanying drawings. Various modifications, additions, and substitutions to the preferred embodiments of the present invention are possible, and the scope of the present invention should not be limited to the following description of the preferred embodiments.

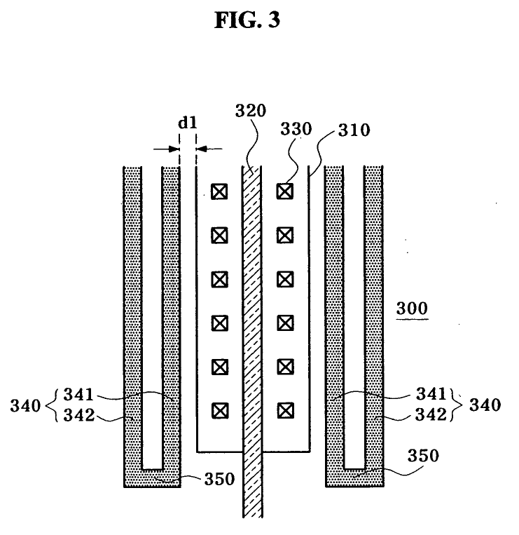

FIG. 3 is a layout view illustrating a semiconductor device having a dummy pattern according to the present invention.

Referring to FIG.3, an active region 310 is defined by a device isolating region 300. That is, the active region 310 is surrounded by the device isolating region 300. Since various devices, such as transistors, are disposed on the active region 310, the active region 310 is provided with a main pattern 320. As used herein, the term main pattern refers to the pattern or patterns that are used to define the actual components of the device, i.e., the patterns that are not “dummy” patterns. The main pattern 320 may be a gate pattern, the other conductive layer pattern, or insulation layer pattern. The main pattern 320 may have a stripe shape as described in the present embodiment, or may have other shapes. In addition to the main pattern 320, the active region 310 is provided with one or more contacts 330. As an example, the contacts 330 may be bit line contacts.

The device isolating region 300 is provided with one or more dummy patterns 340, so that the dummy patterns 340 are spaced apart from the active region 310 by a predetermined distance d1. Here, the distance d1 between one of the dummy patterns 340 and the active region 310 is determined according to a predetermined design rule. As opposed to conventional auxiliary patterns, the dummy patterns 340 are adapted to be transferred from a photomask to a wafer. For this reason, the dummy patterns 340 should be designed so as not to have an unfavorable effect on the operation of the device. In other words, the design rule is determined to prevent the dummy patterns 340 from having an unfavorable effect on the operation of the device. Specifically, the design rule is determined according to parasitic capacitance, implant shadow effect, and bonding region formation procedure.

The dummy patterns 340 serve to cause the main pattern 320 having an isolated pattern shape to be similar to a dense pattern or semi-dense pattern, in order to increase the margin of depth of focus (DOF) in a photolithography process for forming the main pattern 320. Therefore, the dummy patterns 340 have the same stripe shape as the main pattern 320. In this case, the width of the stripe shaped dummy patterns 340 should be determined to ensure easy execution of the photolithography process while preventing the dummy patterns 340 from having an unfavorable effect on the operation of the device. Specifically, the width of the dummy patterns 340 should be determined to restrict parasitic capacitance, to increase the margin of the photolithography process, and to achieve a minimized etching bias.

Although each of the dummy patterns 340 may be formed of a single stripe dummy pattern, it is possible that a plurality of stripe dummy patterns are spaced apart from each other to form the dummy pattern 340. In the present embodiment, each dummy pattern 340 includes first and second stripe dummy patterns 341 and 342, which are spaced apart parallel to each other. As occasion demands, three or more stripe dummy patterns may be combined to form the dummy pattern 340. However, a combination of stripe dummy patterns is problematic because the dummy pattern 340 may be collapsed during the photolithography process, causing the first and second stripe dummy patterns 341 and 342 to have undesired profiles. To solve this problem, a plurality of connector dummy patterns 350 may be provided for interconnecting ends of the first and second stripe dummy patterns 341 and 342. The connector dummy patterns 350 serve to provide the first and second stripe dummy patterns 341 and 342 with a desired structural strength, thereby preventing the collapse of the stripe dummy patterns 341 and 342 after completion of the photolithography process. Although not shown in the accompanying drawings, the connector dummy patterns 350 are interposed between the first and second stripe dummy patterns 341 and 342 to form a trapezoidal portion for interconnecting the neighboring two stripe dummy patterns 341 and 342.

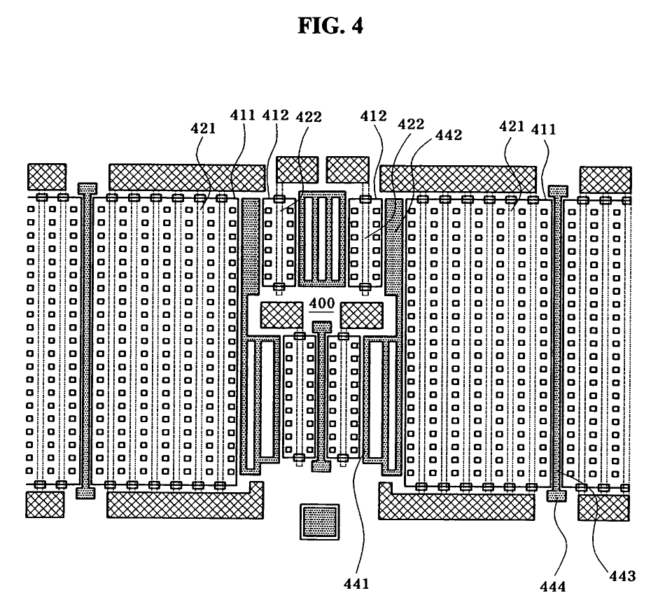

FIG. 4 is a layout view illustrating several different examples of dummy patterns for use in the semiconductor device having a dummy pattern according to the present invention.

Referring to FIG. 4, the semiconductor device includes one or more first active regions 411; one or more second active regions 412; and device isolating regions 400 between the neighboring first active regions 411, between the neighboring second active regions 412, and between the neighboring first and second active regions 411 and 412. Here, the area of the first active region 411 is wider than that of the second active region 412. Also, a plurality of first main patterns 421 having a stripe shape is disposed on the first active region 411 having a relatively wide area, whereas a single second main pattern 422 having a stripe shape is disposed on the second active region 412, having a relatively narrow area.

Each of the device isolating regions 400 is disposed thereon with a dummy pattern 441, 442, or 443. The dummy patterns 441, 442, and 443 are spaced apart from the neighboring active regions by predetermined distances, which are determined according to specific conditions as described with reference to FIG. 3.

In the case of the first of the dummy patterns, i.e. the dummy pattern 441, it is disposed on the device isolating region 400 between the first active region 411 and the second active region 412, so that it is spaced apart from the first active region 411 by a predetermined first distance, and is spaced apart from the second active region 412 by a predetermined second distance. Here, the first and second distances are determined so as to prevent the dummy pattern 441 from having an unfavorable effect on the operation of a device, in accordance with a predetermined design rule. As described above with reference to FIG. 3, the first dummy pattern 441 is formed of a plurality of stripe dummy patterns spaced apart from each other, and connector dummy patterns for interconnecting both ends of the stripe dummy patterns.

In the case of dummy pattern 442, it is disposed on the device isolating region 400 between the first active region 411 and the second active region 412 similar to the dummy pattern 441, but the dummy pattern 442 is formed of a single stripe dummy pattern having a relatively large width differently from the plurality of stripe dummy patterns of the first dummy pattern 441. Accordingly, the second dummy pattern 442 is usable where the width of the device isolating region 400 between the first active region 411 and the second active region 422 is too narrow to insert the plurality of stripe dummy patterns, but is excessively wider than a predetermined width of one of the stripe dummy patterns. Since it is important to keep a desired predetermined distance between the dummy pattern and the active region adjacent thereto, the second dummy pattern 442 is designed to have the maximum width in a range that is spaced apart from the first and second active regions 411 and 412 by the predetermined first and second distances.

Finally, in the case of a third of dummy pattern 443, it is disposed on the device isolating region 400 between the neighboring first active regions 411. The third dummy pattern 443 is used where only one dummy pattern can be inserted into a space between the neighboring active regions. Accordingly, the third dummy pattern 443 has a relatively narrow width. In this case, to prevent the collapse of the third dummy pattern 443, auxiliary dummy patterns 444 are provided at both ends of the third dummy pattern 443. The auxiliary dummy patterns 444 have a width larger than that of the third dummy pattern 443.

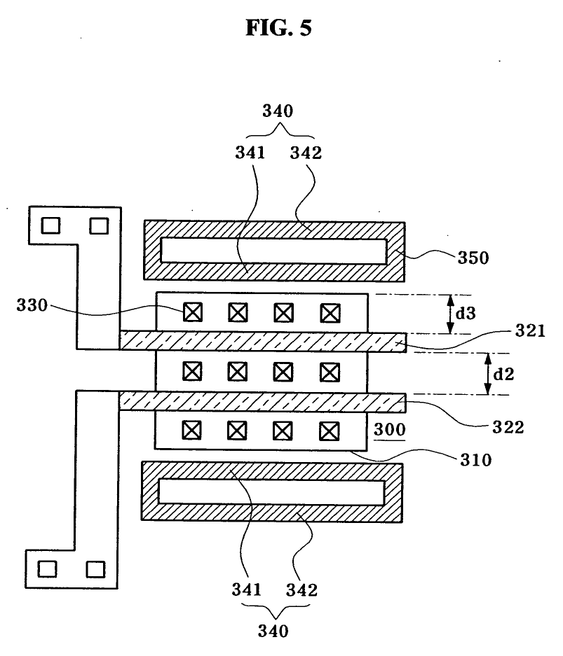

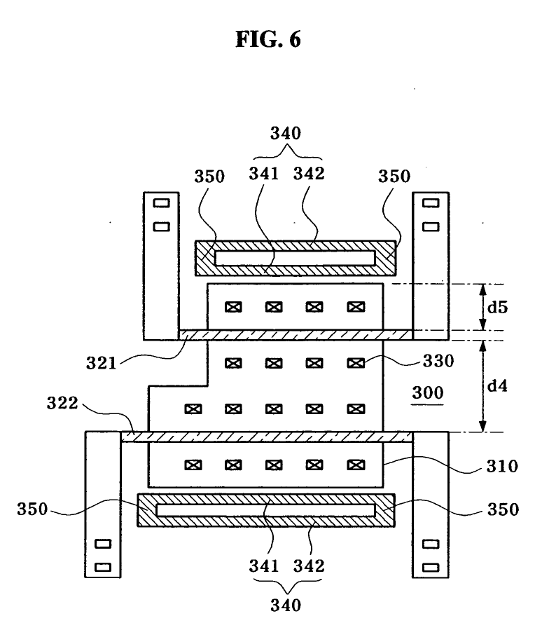

FIG. 5 is a layout view illustrating a desirable design example associated with the semiconductor device having a dummy pattern according to the present invention. FIG. 6 is a layout view illustrating an undesirable design example associated with the semiconductor device having a dummy pattern according to the present invention. In FIGS. 5 and 6, the same reference numerals as those of FIG. 3 denote the same elements, and thus, a detailed description of the same elements will be omitted.

Referring first to FIG. 5, to form main patterns 321 and 322 having the desired profile by use of the dummy patterns 340, it is necessary to appropriately design the main patterns 321 and 322 relative to the active region 310. That is, a distance d2 between the main patterns 321 and 322 should fall in an appropriate range. Also, in a state wherein the main patterns 321 and 322 are disposed on the active region 310, a distance d3 between the main patterns 321 and 322 and the edge of the active region 310, should fall in an appropriate range. If the distances d2 and d3 exceed the appropriate range, this causes an excessive increase in a distance between the active region 310 and the dummy patterns 340, resulting in disadvantageous reduction in the margin of DOF of the isolated pattern by the dummy patterns 340.

From this point of view, as shown in FIG. 6, if a distance d4 between the main patterns 321 and 322 are too large, and a distance d5 between the main patterns 321 and 322 and the edge of the active region 310 are too large, it can be said that the main patterns 321 and 322 are inappropriately designed relative to the active region 310. Accordingly, the main patterns and the active region are designed to achieve an increase in the margin of a DOF of the main patterns by the dummy patterns 340.

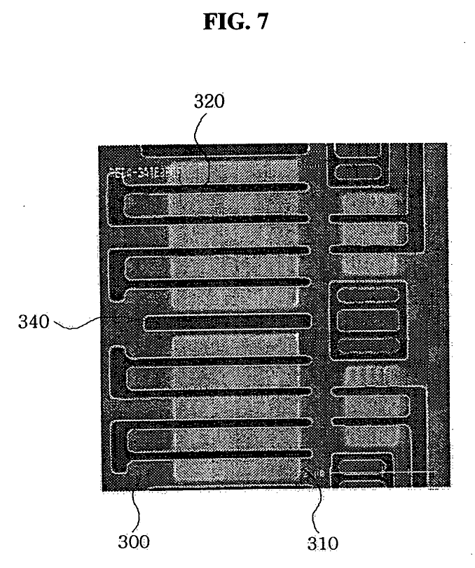

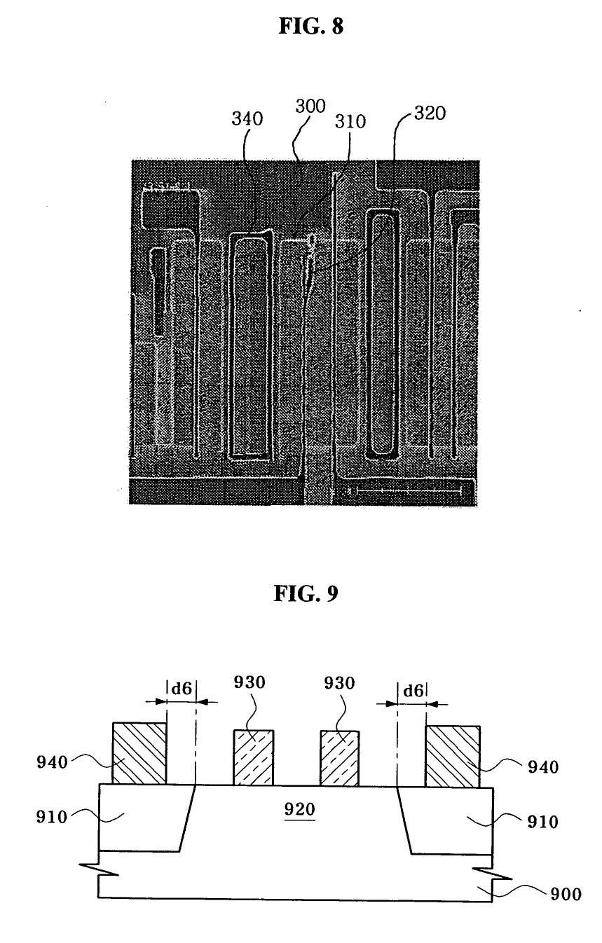

FIG. 7 is a view illustrating the result of patterning the semiconductor device having a dummy pattern according to the present invention using appropriate energy and optimal focus. FIG. 8 is a view illustrating a result of patterning the semiconductor device having a dummy pattern according to the present invention using over-energy and defocus.

As can be understood with reference to FIG. 7, when the main pattern 320 is formed along with the dummy pattern 340 under an appropriate energy and optimal focus condition, the main pattern 320 can achieve a desired profile so long as the dummy pattern 340 is spaced apart from the active region 310 by the desired predetermined distance. Also, as can be understood with reference to FIG. 8, even when the dummy pattern 340 and the main pattern 320 are formed under over-energy and defocus conditions resulting in the collapse of the main pattern 320, the dummy pattern 340 can achieve a desired profile so long as it is spaced apart from the active region 310 by a desired predetermined distance.

FIG. 9 is a sectional view illustrating a method for manufacturing a semiconductor device using a dummy pattern according to the present invention.

According to the method for manufacturing a semiconductor device using a dummy pattern, the material layer to be patterned is first deposited on a semiconductor substrate 900, in which an active region 920 is surrounded by a device isolating region 910. Subsequently, a photoresist layer (not shown) is deposited on the material layer. Then, the photoresist layer is patterned by use of a photo mask having one or more light shielding patterns, to form a photoresist layer pattern (not shown) having an opening for partially exposing a surface of the material layer. Here, the photo mask has a first light shielding pattern, and a second light shielding pattern. The first light shielding pattern corresponds to a material layer pattern 930 that will be formed to overlap with the active region 920. The second light shielding pattern corresponds to a dummy pattern 940 that will be formed on the device isolating region 910 to be spaced apart from the active region 920 by a predetermined distance d6. The photo mask should be designed so that the distance d6 between the dummy pattern 940 and the active region 920 is determined in consideration of a parasitic capacitance, an implant shadow effect, and a bonding region formation procedure, so as to prevent the dummy pattern 940 from having an unfavorable effect on the operation of a device. After patterning the photoresist layer, the material layer pattern 930 and the dummy pattern 940 are formed via an etching process that uses the resulting photoresist layer pattern as an etching mask. Finally, the photoresist layer pattern is removed.

As an alternative example, when forming the dummy pattern 340 and the connector dummy pattern 350 as described with reference to FIG. 3, the present invention may employ a photo mask having: a first light shielding pattern that corresponds to the main pattern 320 to be formed to overlap with the active region 310; second light shielding patterns that correspond to the dummy pattern 340 having a plurality of strip dummy patterns to be formed on the device isolating region 300 while being spaced apart from the active region 310 by the predetermined distance d1; and third light shielding patterns that correspond to the connector dummy patterns 350 used to interconnect the ends of the plurality of strip dummy patterns.

As another alternative example, when forming the dummy pattern 443 and the auxiliary dummy patterns 444 as described with reference to FIG. 4, the present invention may employ a photo mask having: a first light shielding pattern that corresponds to the main pattern 421 to be formed to overlap with the active region 411; a second light shielding pattern that corresponds to the dummy pattern 443 to be formed on the device isolating region 400 while being spaced apart from the active region 411 by the predetermined distance; and third light shielding patterns that correspond to the auxiliary dummy patterns 444 to be formed at both ends of the dummy pattern 443. As described above, the width of the auxiliary dummy patterns 444 are larger than that of the dummy pattern 443.

As yet another alternative example, when forming the dummy pattern 442 as described with reference to FIG. 4, the present invention may employ a photo mask having: a plurality of first light shielding patterns that correspond to the first and second main patterns 421 and 422 to be formed to overlap with the neighboring first and second active regions 411 and 412; and a second light shielding pattern that corresponds to the dummy pattern 442 to be formed on the device isolating region 400 while being spaced apart from the first and second active regions 411 and 412 by the predetermined distances. As described above, the dummy pattern 442 has maximum width within a range that is spaced apart from both the first and second active regions 411 and 412 by the predetermined distances, which are determined to prevent the dummy pattern 442 from having an unfavorable effect on the operation of a device.

As is apparent from the above description, a semiconductor device having a dummy pattern and a method for manufacturing the semiconductor device using the dummy pattern according to the present invention have the following effects:

First, according to the present invention it is possible to achieve a desired main pattern by forming a dummy pattern on a device isolating region. This also has the effect of preventing the dummy pattern from having an unfavorable effect on the operation of the device.

In particular, the present invention is advantageous because the collapse of the dummy pattern can be completely eliminated by forming connector dummy patterns and auxiliary dummy patterns along with the dummy pattern.

Moreover, according to the present invention, the dummy pattern is spaced apart from an active region by an appropriate predetermined distance. This is advantageous because it is possible to obtain the increased process margin and to achieve the uniformity of the critical dimension.

Although the preferred embodiments of the present invention have been disclosed for illustrative purposes, those skilled in the art will appreciate that various modifications, additions and substitutions are possible, without departing from the scope of the invention as disclosed in the accompanying claims.

What is claimed is:

1. A semiconductor device comprising:
a main pattern disposed to overlap with first and second active regions that are separated by a device isolating region; and
a dummy pattern disposed on the device isolating region and spaced apart from the first active region by a predetermined distance, the dummy pattern having first and second stripes arranged in parallel to the main pattern, the first and second stripes provided adjacent to each other.

2. The semiconductor device as set forth in claim 1, wherein the distance between the dummy pattern and the active region is predetermined to prevent the dummy pattern from having an unfavorable effect on the operation of the device.

3. The semiconductor device as set forth in claim 2, wherein the distance between the dummy pattern and the active region is predetermined in consideration of a parasitic capacitance, an implant shadow effect, and a bonding region formation procedure.

4. The semiconductor device as set forth in claim 1, wherein the first and second stripes are connected to each other on at least one end.

5. The semiconductor device as set forth in claim 4, wherein the first and second stripes are separated by a width to restrict a parasitic capacitance, increase the margin of a photolithography process, and obtain a minimized etching bias.

6. The semiconductor device as set forth in claim 4, wherein the main pattern has a stripe shape.

7. The semiconductor device as set forth in claim 4, further comprising:
a pair of auxiliary dummy patterns arranged at both ends of the first stripe dummy pattern, the auxiliary dummy patterns having a width larger than that of the first stripe dummy pattern.

8. A semiconductor device comprising:
first and second main patterns disposed to overlap with first and second active regions, respectively, which are separated from each other by a device isolating region; and
a dummy pattern disposed on the device isolating region to be spaced apart from the first and second active regions by first and second distances that are configured to prevent the dummy pattern from having an unfavorable effect on the operation of the device, the dummy pattern being provided with a that would enable the dummy pattern to maintain the first and second distances with the first and second active regions.

9. The semiconductor device as set forth in claim 8, wherein the first and second distances between the first and second active regions and the dummy pattern are determined in consideration of a parasitic capacitance, an implant shadow effect, and a bonding region formation procedure.

10. A method for manufacturing a semiconductor device comprising:
depositing a layer of material to be patterned on a substrate on which first and second active regions are separated by a device isolating region;
depositing a photoresist layer on the layer of material;
patterning the photoresist layer using a photomask, the photomask having a first light shielding pattern that corresponds to a first pattern corresponding to a pattern to be formed to overlap with at least the first active region, and a second light shielding pattern that corresponds to a second dummy pattern to be disposed on the device isolating region while being spaced apart from the first active region by a predetermined distance;
patterning the layer of material and providing the layer of material with the first pattern that defines a component of device; and
removing the photoresist layer patterns.

11. The method as set forth in claim 10, wherein the distance between the dummy pattern and the active region is determined in a range to prevent the dummy pattern from exerting an unfavorable effect on the operation of the device.

12. The method as set forth in claim 11, wherein the distance between the dummy pattern and the active region is determined in consideration of a parasitic capacitance, an implant shadow effect, and a bonding region formation procedure.

13. The method as set forth in claim 10, wherein the dummy pattern has a stripe shape arranged in parallel to the material layer pattern.

14. The method as set forth in claim 13, wherein a width of the stripe shaped dummy pattern is determined in a range to restrict a parasitic capacitance, to increase the margin of a photolithography process, and to obtain a minimized etching bias.

15. The method as set forth in claim 13, wherein the dummy pattern includes a plurality of stripe dummy patterns spaced apart from each other.
